(19) United States
(12) Patent Application Publication
(10) Pub. No.: US 2008/0163928 A1
(43) Pub. Date: Jul. 10, 2008

(54) Photovoltaic Cell Containing a Semiconductor Photovoltaically Active Material

(76) Inventor: Hans-Josef Sterzel, Dannstadt-Schauernheim (DE)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/817,167

(22) PCT Filed: Mar. 7, 2006
(86) PCT No.: PCT/EP06/60522

§ 371 Date: Aug. 27, 2007

(30) Foreign Application Priority Data
Mar. 9, 2005 (DE) 10 2005 010790.7

(51) Int. Cl. H01L 31/0296; H01L 31/04; C23C 14/14; H01L 31/032; H01L 21/00; C23C 14/34; C25D 7/12

(52) U.S. Cl. 136/264; 204/192.25; 205/244; 427/76; 438/95; 257/E21.001

(57) ABSTRACT

The invention relates to a photovoltaic cell and to a process for producing a photovoltaic cell comprising a photovoltaically active semiconductor material of the formula (I) or (II):

ZnTe (I)

Zn₁₋ₓMnₓTe (II)

where x is from 0.01 to 0.7, wherein the photovoltaically active semiconductor material comprises a metal halide comprising a metal selected from the group consisting of germanium, tin, antimony, bismuth and copper and a halogen selected from the group consisting of fluorine, chlorine, bromine and iodine

The invention relates to photovoltaic cells and the photovoltaically active semiconductor material present therein.

Photovoltaically active materials are semiconductors which convert light into electric energy. The principles of this have been known for a long time and are utilized industrially. Most of the solar cells used industrially are based on crystalline silicon (single-crystal or polycrystalline). In a boundary layer between p- and n-conducting silicon, incident photons excite electrons of the semiconductor so that they are raised from the valence band to the conduction band.

The magnitude of the energy gap between the valence band and the conduction band limits the maximum possible efficiency of the solar cell. In the case of silicon, this is about 30% on irradiation with sunlight. In contrast, an efficiency of about 15% is achieved in practice because some of the charge carriers recombine by various processes and are thus no longer effective.

DE 102 23 744 A1 discloses alternative photovoltaically active materials and photovoltaic cells in which these are present, which have the loss mechanisms which reduce efficiency to a lesser extent.

With an energy gap of about 1.1 eV, silicon has quite a good value for practical use. A decrease in the energy gap will push more charge carriers into the conduction band, but the cell voltage becomes lower. Analogously, larger energy gaps would result in higher cell voltages, but because fewer photons are available to be excited, lower usable currents are produced.

Many arrangements such as series arrangement of semiconductors having different energy gaps in tandem cells have been proposed in order to achieve higher efficiencies. However, these are very difficult to realize economically because of their complicated structure.

A new concept comprises generating an intermediate level within the energy gap (up-conversion). This concept is described, for example, in Proceedings of the 14^{th} Workshop on Quantum Solar Energy Conversion-Quantasol 2002, Mar. 17-23, 2002, Rauris, Salzburg, Austria, “Improving solar cells efficiencies by the up-conversion”, T I. Trupke, M. A. Green, P. Wurfel or “Increasing the Efficiency of Ideal Solar Cells by Photon Induced Transitions at intermediate Levels”, A. Luque and A. Marti, Phys. Rev. Letters, Vol. 78, No. 26, June 1997, 5014-5017. In the case of a band gap of 1.995 eV and an energy of the intermediate level of 0.713 eV, the maximum efficiency is calculated to be 63.17%.

Such intermediate levels have been confirmed spectroscopically, for example in the system Cd_{1-y}Mn_{y}OₓTe₁₋ₓ or Zn₁₋ₓMnₓO_{y}Te_{1-y}. This is described in “Band anticrossing in group II-OₓVI₁₋ₓ highly mismatched alloys: Cd_{1-y}Mn_{y}OₓTe₁₋ₓ quaternaries synthesized by 0 ion implantation”, W. Walukiewicz et al., Appl. Phys. Letters, Vol 80, No. 9, March 2002, 1571-1573, and in “Synthesis and optical properties of II-O-VI highly mismatched alloys”, W. Walukiewicz et al., Appl. Phys. Vol 95, No. 11, June 2004, 6232-6238. According to these authors, the desired intermediate energy level in the band gap is raised by part of the tellurium anions in the anion lattice being replaced by the significantly more electronegative oxygen ion. Here, tellurium was replaced by oxygen by means of ion implantation in thin films. A significant disadvantage of this class of materials is that the solubility of oxygen in the semiconductor is extremely low. This results in, for example, the compounds Zn₁₋ₓMnₓTe_{1-y}O_{y} in which y is greater than 0.001 being thermodynamically unstable. On irradiation over a prolonged period, they decompose into the stable tellurides and oxides. Replacement of up to 10 atom % of tellurium by oxygen would be desirable, but such compounds are not stable.

Zinc telluride, which has a direct band gap of 2.25 eV at room temperature, would be an ideal semiconductor for the intermediate level technology because of this large band gap. Zinc in zinc telluride can readily be replaced continuously by manganese, with the band gap increasing to about 2.8 eV for MnTe (“Optical Properties of epitaxial ZnMnTe and ZnMgTe films for a wide range of alloy compositions”, X. Liu et al., J. Appl. Phys. Vol. 91, No. 5, March 2002, 2859-2865; “Bandgap of Zn₁₋ₓMnₓTe: non linear dependence on composition and temperature”, H. C. Mertins et al., Semicond. Sci. Technol. 8 (1993) 1634-1638).

Zn₁₋ₓMnₓTe can be doped with up to 0.2 mol % of phosphorus to make it p-conductive, with an electrical conductivity in the range from 10 to 30 Ω⁻¹cm⁻¹ (“Electrical and Magnetic Properties of Phosphorus Doped Bulk Zn₁₋ₓMnₓTe”, Le Van Khoi et al., Moldavian Journal of Physical Sciences, No. 1, 2002, 11-14). Partial replacement of zinc by aluminum gives n-conductive species (“Aluminium-doped n-type ZnTe layers grown by molecular-beam epitaxy”, J. H. Chang et al., Appl. Phys. Letters, Vol 79, No. 6, August 2001, 785-787; “Aluminium doping of ZnTe grown by MOPVE”, S. I. Gheyas et al., Appl. Surface Science 100/101 (1996) 634-638; “Electrical Transport and Photoelectronic Properties of ZnTe: Al Crystals”, T. L. Lavsen et al., J. Appl. Phys., Vol 43, No. 1, January 1972, 172-182). At degrees of doping of about 4*10¹⁸ Al/cm³, electrical conductivities of from about 50 to 60 Ω⁻¹cm⁻¹ can be achieved.

A photovoltaic cell which has a high efficiency and a high electric power comprises, for example, a photovoltaically active semiconductor material, wherein the photovoltaically active semiconductor material is a p- or an n-doped semiconductor material comprising a binary compound of the formula (A) or a ternary compound of the formula (B):

ZnTe (A)

Zn₁₋ₓMnₓTe (B)

where x is from 0.01 to 0.99, and a particular proportion of tellurium ions in the photovoltaically active semiconductor material has been replaced by halogen ions and nitrogen ions and the halogen ions are selected from the group consisting of fluoride, chloride and bromide and mixtures thereof. It is necessary to replace tellurium ions in the ZnTe both by nitrogen ions and by halogen ions.

The introduction of nitrogen and halogen can be achieved, for example, by treatment of Zn₁₋ₓMnₓTe layers with NH₄Cl at elevated temperature. However, this has the advantage that solid NH₄Cl grows on the relatively cooler reactor walls and the reactor thus becomes contaminated with NH₄Cl in an uncontrollable fashion.

It is an object of the present invention to provide a photovoltaic cell which has a high efficiency and a high electric power and avoids the disadvantages of the prior art. A further object of the present invention is to provide, in particular, a photovoltaic cell comprising a thermodynamically stable photovoltaically active semiconductor material which comprises an intermediate level in the energy gap.

This object is achieved according to the invention by a photovoltaic cell comprising a photovoltaically active semiconductor material of the formula (I) or (II):

ZnTe (I)

Zn₁₋ₓMnₓTe (II)

where x is from 0.01 to 0.7, and the photovoltaically active semiconductor material comprises ions of at least one metal halide comprising a metal selected from the group consisting of germanium, tin, antimony, bismuth and copper and a halide selected from the group consisting of fluorine, chlorine, bromine and iodine.

It has been found that it is possible to introduce halide ions into the semiconductor material of the formula (I) or (II) in such a way that simultaneous doping with nitrogen ions is not necessary. It is therefore also not necessary to replace part of the zinc by manganese, which in the end leads to a simpler system. In the photo-voltaic cell of the invention, particular preference is accordingly given to using a photovoltaically active semiconductor material of the formula (I) or preferably a photovoltaically active semiconductor material of the formula (II) which comprises the halide ions.

It has completely surprisingly been found that the semiconductor materials comprising metal halides used in the photovoltaic cell of the invention have high Seebeck coefficients up to 100 μV/degree together with a high electrical conductivity. Such behavior has hitherto not been described for semiconductors having band gaps above 1.5 eV. This behavior shows that the novel semiconductors can be activated not only optically but also thermally and thus contribute to better utilization of light quanta.

The photovoltaic cell of the invention has the advantage that the photovoltaically active semiconductor material with the metal halide ions which is used is thermodynamically stable. Furthermore, the photovoltaic cells of the invention have high efficiencies above 15%, since the metal halide ions present in the semiconductor material produce an intermediate level in the energy gap of the photovoltaically active semiconductor material. Without an intermediate level, only photons having at least the energy of the energy gap could raise electrons or charge carriers from the valence band into the conduction band. Photons having a higher energy also contribute to the efficiency, with the excess energy compared to the band gap being lost as heat. In the case of the intermediate level which is present in the semiconductor material used according to the present invention and can be partly occupied, more photons can contribute to excitation.

The metal halide present in the photovoltaically active semiconductor material preferably comprises at least one metal halide from the group consisting of CuF₂, BiF₃, BiCl₃, BiBr₃, BiI₃, SbF₃, SbCl₃, SbBr₃, GeI₄, SnBr₂, SnF₄, SnCl₂ and SnI₂.

In a preferred embodiment of the present invention, the metal halide is present in the photovoltaically active semiconductor material in a concentration of from 0.001 to 0.1 mol per mole of telluride, particularly preferably from 0.005 to 0.05 mol per mol of telluride.

The photovoltaic cell of the invention comprises, for example, a p-conducting absorber layer comprising the semiconductor material comprising the metal halide. This absorber layer comprising the p-conducting semiconductor material is adjoined by an n-conducting contact layer which preferably does not absorb the incident light, for example a layer of n-conducting transparent metal oxides such as indium-tin oxide, fluorine-doped tin dioxide or Al-, Ga- or In-doped zinc oxide. Incident light generates a positive charge and a negative charge in the p-conducting semiconductor layer. The charges diffuse in the p region. Only when the negative charge reaches the p-n boundary can it leave the p region. A current flows when the negative charge has reached the front contact applied to the contact layer.

In a further preferred embodiment of the present invention, the photovoltaic cell of the invention comprises a p-conducting contact layer comprising the semiconductor material comprising the ions of the metal halide. This p-conducting contact layer is preferably located on an n-conducting absorber which comprises, for example, a germanium-doped bismuth sulfide. Examples of germanium-doped bismuth sulfide (BiₓGe_{y}S_{z}) are Bi_{1.98}Ge_{0.02}S₃ or Bi_{1.99}Ge_{0.02}S₃. However, other n-conducting absorbers known to those skilled in the art are also possible. in a preferred embodiment of the photovoltaic cell of the invention, it comprises an electrically conductive substrate, a p or n layer of the semiconductor material of the formula (I) or (II) comprising metal halides having a thickness of from 0.1 to 20 m, preferably from 0.1 to 10 μm, particularly preferably from 0.3 to 3 μm, and an n layer or p layer of an n- or p-conducting semiconductor material having a thickness of from 0.1 to 20 μm, preferably from 0.1 to 10 μm, particularly preferably from 0.3 to 3 μm. The substrate is preferably a flexible metal foil or a flexible metal sheet. The combination of a flexible substrate with thin photovoltaically active layers gives the advantage that no complicated and thus expensive support has to be used for holding the solar module comprising the photovoltaic cells of the invention. In the case of nonflexible substrates such as glass or silicon, wind forces have to be dissipated by means of complicated support constructions in order to avoid breakage of the solar module. On the other hand, if deformation due to flexibility is possible, very simple and inexpensive support constructions which do not have to be rigid under deformation forces can be used. In particular, a stainless steel sheet is used as preferred flexible substrate for the purposes of the present invention.

The invention further provides a process for producing a photovoltaic cell according to the invention, which comprises the steps:
production of a layer of the semiconductor material of the formula (I) or (II) and
introduction of a metal halide comprising a metal selected from the group consisting of copper, bismuth, germanium and tin and a halogen selected from the group consisting of fluorine, chlorine, bromine or iodine into the layer.

The layer produced from the semiconductor material of the formula (I) or (II) preferably has a thickness of from 0.1 to 20 μm, more preferably from 0.1 to 10 μm, particularly preferably from 0.3 to 3 μm. This layer is preferably produced by at least one deposition method selected from the group consisting of sputtering, electrochemical deposition or electroless deposition. The term sputtering refers to the ejection of clusters comprising from about 1000 to 10 000 atoms from a sputtering target serving as electrode by means of accelerated ions and the deposition of the ejected material on a substrate. The layers of the semiconductor material of the formula (I) or (II) which are produced by the process of the invention are particularly preferably produced by sputtering, because sputtered layers have a higher quality. However, the deposition of zinc on a suitable substrate and subsequent reaction with a Te vapor at temperatures below 400° C. in the presence of hydrogen is also possible. A further suitable method is electrochemical deposition of ZnTe to produce a layer of the semiconductor material of the formula (I) or (II).

The introduction of a metal halide comprising a metal selected from the group consisting of copper, antimony, bismuth, germanium and tin and a halogen selected from the group consisting of fluorine, chlorine, bromine and iodine into the layer of the semiconductor material is achieved, according to the invention, by bringing the layer into contact with a vapor of the metal halide. Here, the layer of the semiconductor material of the formula (I) or (II) is preferably brought into contact with the vapor of the metal halide at temperatures of from 200 to 1000° C., particularly preferably from 500 to 900° C.

Particular preference is given to introducing the metal halide during the synthesis of the zinc telluride in evacuated fused silica vessels. In this case, zinc, if appropriate manganese, tellurium and the metal halide or mixtures of metal halides are introduced into the fused silica vessel, the fused silica vessel is evacuated and flame sealed under reduced pressure. The fused silica vessel is then heated in a furnace, firstly quickly to about 400° C. because no reaction takes place below the melting point of Zn and Te. The temperature is then increased more slowly at rates of from 20 to 100° C./h to from 800 to 1200° C., preferably to from 1000 to 1100° C. The formation of the solid state structure takes place at this temperature. The time necessary for this is from 1 to 20 h, preferably from 2 to 10 h. Cooling then takes place. The content of the fused silica vessel are broken up with exclusion of moisture to particle sizes of from 0.1 to 1 mm and these particles are then comminuted, e.g. in a ball mill, to particle sizes of from 1 to 30 μm, preferably from 2 to 20 μm. Sputtering targets are then produced from the resulting powder by hot pressing at from 400 to 1200° C., preferably from 600 to 800° C., and pressures of from 100 to 5000 kp/cm², preferably from 200 to 2000 kp/cm².

In the process of the invention, metal halides are preferably introduced into the layer of the semiconductor material of the formula (I) or (II) in a concentration of from 0.001 to 0.1 mol per mole of telluride, particularly preferably from 0.005 to 0.05 mol per mole of telluride.

In further process steps known to those skilled in the art, the photovoltaic cell of the invention is finished by means of the process of the invention.

### EXAMPLES

The examples were carried out using powders rather than thin layers. The measured properties of the semiconductor materials comprising metal halides, e.g. energy gap, conductivity or Seebeck coefficient, are not thickness-dependent and are therefore equally valid.

The compositions indicated in the table of results were produced in evacuated fused silica tubes by reaction of the elements in the presence of metal halides. For this purpose, the elements having a purity of in each case better than 99.99% were weighed into fused silica tubes, the residual moisture was removed by heating under reduced pressure and the tubes were flame sealed under reduced pressure. The tubes were heated over a period of 20 h from room temperature to 1100° C. in a slanting tube furnace and the temperature was then maintained at 1100° C. for 5 h. The furnace was then switched off and allowed to cool.

After cooling, the tellurides produced in this way were comminuted in an agate mortar to produce powders having particle sizes of less than 30 μm. These powders were pressed at room temperature under a pressure of 3000 kp/cm² to produce disks having a diameter of 13 mm.

A disk having a grayish black color and a slight reddish sheen was obtained in each case.

In a Seebeck experiment, the materials were heated to 130° C. on one side while the other side was maintained at 30° C. The open-circuit voltage was measured by means of a voltmeter. This value divided by 100 gives the mean Seebeck coefficient indicated in the table of results.

In a second experiment, the electrical conductivity was measured. The absorptions in the optical reflection spectrum indicated the values of the band gap between valence band and conduction band as from 2.2 to 2.3 eV and in each case an intermediate level at from 0.8 to 0.95 eV.

Table of results

| | Seebeck coefficient | Electrical conductivity |
|---|---|---|
| Composition | μV/° | S/an |
| ZnTe(BiF₃)_{0.005} | 350 | 280 |
| ZnTe(BiF₃)_{0.02} | 300 | 580 |
| ZnTe(BiI₃)_{0.005} | 360 | 550 |
| ZnTe(CuF₂)_{0.005} | 530 | 50 |
| ZnTe(CuF₂)_{0.002} | 200 | 150 |
| ZnTe(CuI₂)_{0.005} | 450 | 310 |
| ZnTe(SnF₄)_{0.005} | 400 | 70 |
| ZnTe(SnF₄)_{0.02} | 420 | 380 |
| ZnTe(SnBr₂)_{0.02} | 260 | 30 |
| ZnTe(GeI₄)_{0.02} | 180 | 100 |
| Zn_{0.6}Mn_{0.4}Te(SnF₄)_{0.02} | 350 | 0.1 |
| ZnTe(SbF₃)_{0.005} | 350 | 520 |
| ZnTe(SbCl₃)_{0.005} | 360 | 480 |
| ZnTe(SbBr₃)_{0.005} | 320 | 520 |
| ZnTe(SnI₂)_{0.01} | 250 | 210 |
| ZnTe(SnCl₂)_{0.01} | 180 | 80 |

1: A photovoltaic cell comprising a photovoltaically active semiconductor material of the formula (I) or (II):
ZnTe (I)
Zn₁₋ₓMnₓTe (II)
where x is from 0.01 to 0.7, wherein the photovoltaically active semiconductor material comprises a metal halide comprising a metal selected from the group consisting of germanium, tin, antimony, bismuth and copper and a halogen selected from the group consisting of fluorine, chlorine, bromine and iodine.

2: The photovoltaic cell according to claim 1, wherein the metal halide comprises ions of at least one metal halide selected from the group consisting of CuF₂, BiF₃, BiCl₃, BiBr₃, BiI₃, SbF₃, SbCl₃, SbBr₃, GeI₄, SnBr₂, SnF₄, SnCl₂ and SnI₂.

3: The photovoltaic cell according to claim 1, wherein the metal halide is present in the photovoltaically active semiconductor material in a concentration of from 0.001 to 0.1 mol per mole of telluride.

4: The photovoltaic cell according to claim 1, wherein a p-conducting absorbent layer comprising the semiconductor material comprising the metal halide is present.

5: The photovoltaic cell according to claim 1, wherein a p-conducting contact layer comprising the semiconductor material comprising the metal halide is present.

6: The photovoltaic cell according to claim 5, wherein the p-conducting contact layer is located on an n-conducting absorber comprising a germanium-doped bismuth sulfide.

7: A process for producing a photovoltaic cell according to claim 1, which comprises the production of a layer of the semiconductor material of the formula (I) or (II) and introduction of a metal halide comprising a metal selected from the group consisting of copper, bismuth, germanium and tin and a halogen selected from the group consisting of fluorine, chlorine, bromine and iodine into the layer.

8: The process according to claim 7, wherein a layer of the semiconductor material of the formula (I) or (II) having a thickness of from 0.1 to 20 μm is produced.

9: The process according to claim 7, wherein the layer is produced by means of at least one deposition process selected from the group consisting of sputtering, electrochemical deposition and electroless deposition.

10: The process according to claim 7, wherein the introduction of the metal halide is effected by bringing the layer into contact with a vapor of the metal halide at a temperature of from 200° C. to 1000° C.
